(19) United States
(12) Patent Application Publication
(10) Pub. No.: US 2025/0069914 A1
(43) Pub. Date: Feb. 27, 2025

(54) SUBSTRATE DEGAS STATION

(71) Applicant: Applied Materials, Inc., Santa Clara, CA (US)

(72) Inventors: Thomas BREZOCZKY, Los Gatos, CA (US); Punnati KRUSHNA REDDY, Bangalore (IN); Azhar ALI M.A., Bangalore (IN); Kirankumar Neelasandra SAVANDAIAH, Bangalore (IN); Lakshmikanth Krishnamurthy SHIRAHATTI, Bangalore (IN); Dhritiman Subha KASHYAP, Bangalore (IN)

(21) Appl. No.: 18/811,897

(22) Filed: Aug. 22, 2024

(30) Foreign Application Priority Data
Aug. 25, 2023 (IN) 202341057081

(51) Int. Cl. H01L 21/67; H01L 21/677; H01L 21/687

(52) U.S. Cl. CPC H01L 21/67115; H01L 21/67709; H01L 21/68742

(57) ABSTRACT

Degas stations for degassing substrates that are conveyed through a substrate processing system on a magnetically levitated carrier and related methods are provided. The degas station includes a housing, a magnetic levitation system coupled to the housing configured to levitate and move a carrier within the housing, a first heater assembly and a second heater assembly. The first heater assembly is disposed in the housing. The first heater assembly includes a first support, a first reflector disposed within the housing by the first support, and a first heat source coupled to reflector. The second heater assembly is disposed in the housing above the first heater assembly. The second heater assembly includes a second support, a second reflector disposed within the housing by the second support, and a second heat source coupled to the second reflector. At least one substrate support member is disposed between the first heater assembly and the second heater assembly.

### CROSS-REFERENCE TO RELATED APPLICATIONS

This application claims priority to and the benefit of India Provisional Patent Application No. IN 202341057081 entitled “SUBSTRATE DEGAS STATION” filed Aug. 25, 2023. The aforementioned application is incorporated by reference herein.

### BACKGROUND

### Field

Embodiments described herein generally relate to semiconductor processes and, more particularly, to semiconductor process equipment used to degas semiconductor substrates.

### Description of the Related Art

Semiconductor devices are typically formed on semiconductor substrates using processing systems which include several process chambers, where each process chamber is used to complete one or more of the various steps (e.g., depositions) to form the semiconductor devices (e.g., a memory chip). Processing systems may use degas systems to remove volatile compounds, such as water vapor, from the substrate prior to pre-cleaning and depositing a layer on the substrate. However, the heating elements used to create heat within a degas system are disposed at fixed locations within a processing region of a process chamber. Thus, the heat from the heating elements is not targeted at the substrate, requiring heating of the interior volume of the degas system which increases power consumption and causes unnecessary heating of chamber components. Additionally, degas systems have a tendency to cause uneven heating of the substrate which can lead to unsatisfactory degassing of the substrate as well as causing damage to the substrate at localized hotspots.

Therefore, there is a need in the art for a degas system that reduces the volume heated by the heating elements, as well as a need in the art for a degas system that more uniformly heats the substrate.

### SUMMARY

In one embodiment, a degas station is provided. The degas station includes a housing, a magnetic levitation system coupled to the housing configured to levitate and move a carrier within the housing, a first heater assembly and a second heater assembly. The first heater assembly is disposed in the housing. The first heater assembly includes a first support, a first reflector disposed within the housing by the first support, and a first heat source coupled to reflector. The second heater assembly is disposed in the housing above the first heater assembly. The second heater assembly includes a second support, a second reflector disposed within the housing by the second support, and a second heat source coupled to the second reflector. At least one substrate support member is disposed between the first heater assembly and the second heater assembly.

In one embodiment, a degas station is provided. The degas station includes a housing, a magnetic levitation system coupled to the housing and configured to levitate and move a carrier within the housing, a first heater assembly, and a reflector assembly. The first heater assembly is disposed in housing. The first heater assembly includes a first support connected to the housing, a first reflector connected to the first support, and a first heat source coupled to the first reflector. The reflector assembly is disposed in the housing. The reflector assembly includes a second support connected to the housing, and a second reflector supported by the second support. At least one substrate support member is disposed between the first heater assembly and the reflector assembly.

In one embodiment, a degas station is provided. The degas station includes a housing, a magnetic levitation system coupled to the housing and configured to levitate and move a carrier within the housing, a reflector assembly, and a heater assembly. The reflector assembly is disposed in the housing. The reflector assembly includes a first support coupled to the housing, and a first reflector connected to the first support. The heater assembly is disposed in the housing beneath the reflector assembly. The heater assembly includes a second support coupled to the housing, a second reflector connected to the second support, a heat source connected to the second reflector, and at least one lift pin. At least one substrate support member is disposed between the heater assembly and the reflector assembly.

In one embodiment, a method of degassing a substrate in a degas station is provided. The method includes magnetically levitating a carrier with a substrate disposed thereon in a first position between a reflector assembly and a heater assembly disposed within a housing of the station. The method further includes moving both the reflector assembly and the heater assembly from a retracted position to an extended position while the carrier is disposed between the reflector assembly and heater assembly. The method further includes degassing the substrate disposed on the carrier with the heater assembly while the reflector assembly and heater assembly are each in the extended position, wherein the degassing includes pumping a purge gas through a gas port formed in at least one of the reflector assembly or the heater assembly towards the substrate.

In one embodiment, a method of degassing a substrate in a degas station is provided. The method includes positioning a substrate disposed on a carrier above one or more lift pins of a first heater assembly and below a reflector assembly, and transferring the substrate from the carrier to the lift pins by lowering the carrier. The method further includes moving the carrier from under the reflector assembly, lowering the reflector assembly to place a reflector of the reflector assembly in a degas position above the substrate, and degassing the substrate with the first heating unit.

In one embodiment, a method of degassing a substrate in a degas station is provided. The method includes positioning a substrate disposed on a carrier above one or more lift pins of a reflector assembly and above a heater assembly in a first position, and transferring the substrate from the carrier to the lift pins by raising the heater assembly from the a first position to a second position to engage the lift pins with the substrate. The method further includes moving the carrier from under the reflector assembly, lowering the reflector assembly to place a reflector of the reflector assembly in a degas position above the substrate, and degassing the substrate with the heater assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, which may admit to other equally effective embodiments.

FIG. 1 illustrates a schematic plan view of an example substrate processing system, in which embodiments of the present disclosure may be implemented.

FIG. 2A is a cross-sectional view of an exemplary degas station, according to embodiments described herein.

FIG. 2B is a perspective view of an exemplary heat source, according to embodiments described herein.

FIG. 2C is a cross-sectional view of the exemplary heat source, according to embodiments described herein.

FIG. 3 is a cross-sectional view of an exemplary degas station, according to embodiments described herein.

FIG. 4 is a cross-sectional view of an exemplary degas station, according to embodiments described herein.

FIG. 5A is cross-sectional view of an exemplary degas station showing a substrate transferred to lift pins of a lower heater assembly from a carrier, according to some embodiments.

FIG. 5B is a cross-sectional view of the exemplary degas station shown in FIG. 5A and illustrates the substrate supported on the lift pins after the carrier is moved to a park position.

FIG. 5C is a cross-sectional view of the exemplary degas station shown in FIG. 5A and illustrates a reflector assembly in a degas position.

FIG. 6 is a cross-sectional view of an exemplary degas station, according to embodiments described herein.

FIG. 7 illustrates a side view of a portion of an example station of the substrate processing system of FIG. 1 with a degas assembly, in which embodiments of the present disclosure may be implemented.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a degas station for degassing substrates that are conveyed through a substrate processing system on a magnetically levitated carrier.

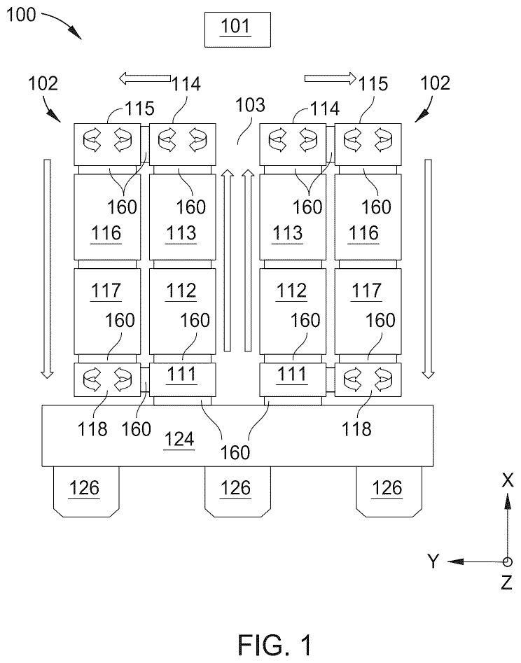

FIG. 1 illustrates a plan schematic view of an example substrate processing system 100, in which embodiments of the present disclosure may be implemented. The substrate processing system 100 includes a controller 101 and one or more processing lines 102.

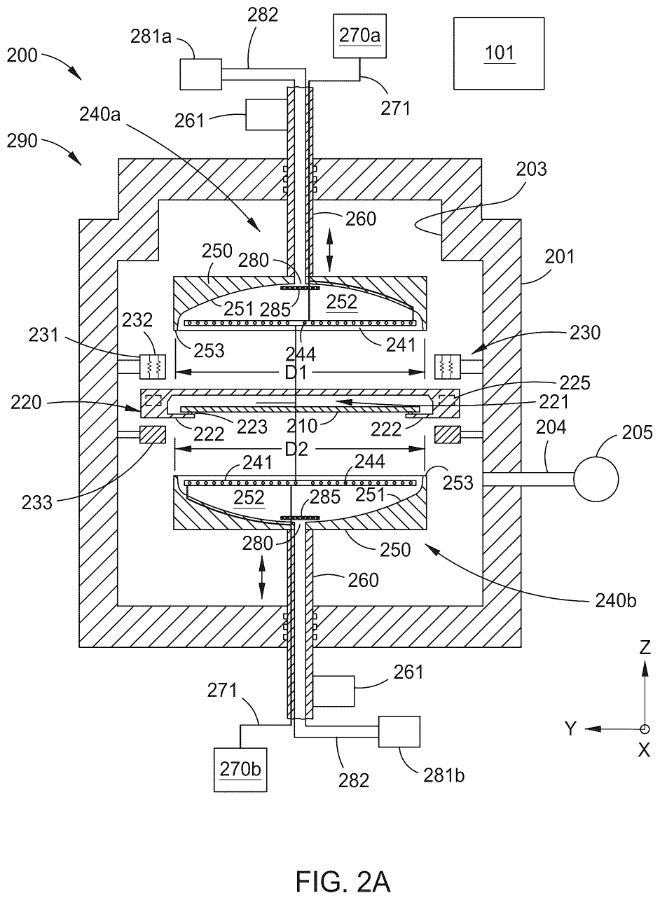

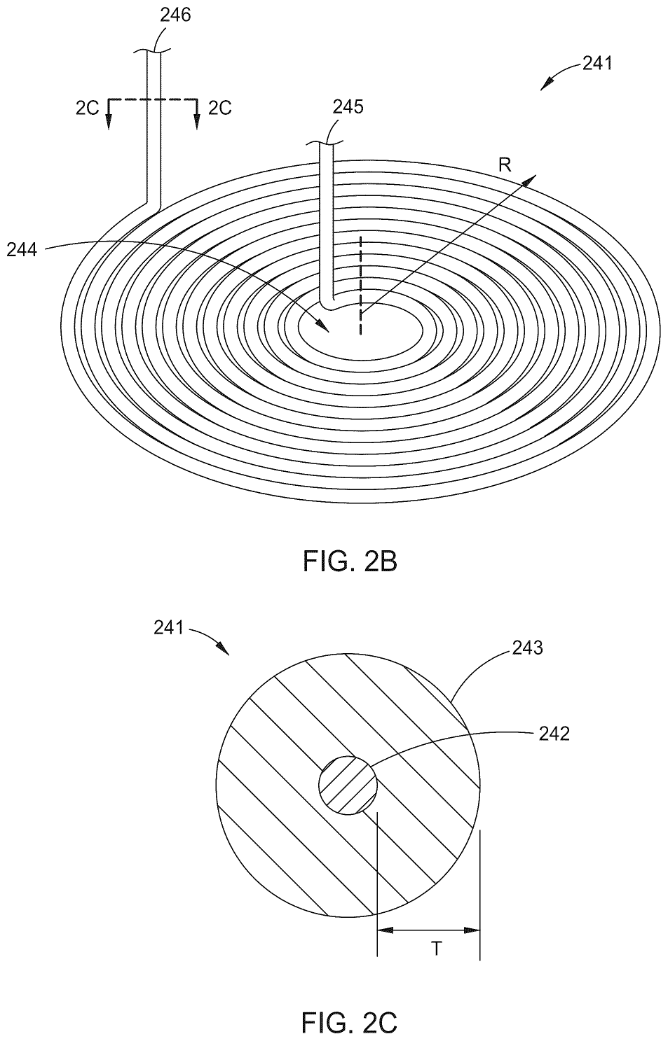

The one or more processing lines 102 each include a plurality of stations (e.g., stations 111-118), as illustrated in FIG. 1. In one example, the processing line 102 illustrated on the right side of FIG. 1 includes at least four process stations 112, 113, 116, and 117, the processing line 102 illustrated on the left side of FIG. 1 includes at least four process stations 112, 113, 116, and 117. However, process stations 111, 114, and 115 may also be configured to perform one or more substrate processing processes. Each processing line 102 may include a magnetic transportation system formed from the individual magnetic levitation assemblies of the stations 111-118 that are configured to convey an object disposed on a carrier (e.g., carrier 220 shown in FIG. 2A) through the processing line 102. The magnetic levitation assemblies may be magnetic rails configured to levitate the carrier and to convey the carrier. Each processing line 102 may be independent of other processing lines. The processing lines 102 may be physically separated by one another by a gap 103. The gap 103 may be sized such that a technician may walk between each processing line 102 to service the one or more stations 111-118.

Each processing line 102 may include a plurality of slit valves 160 to selectively isolate each station 111-118. The slit valves 160 may be selectively opened and closed to allow a clear path for the travel of the carrier, to selectively isolate the stations 111-118 from one another, and to facilitate the pressurization or depressurization of the stations 111-118.

The substrate processing system 100 may be used to process multiple substrates in each processing line 102 to produce a desired fabricated substrate. In some cases, the substrate processing system 100 may be a PVD system. For example, the first station 111 may be a first load lock, the second station 112 may be a degas station, the third station 113 may be a pre-clean station, the fourth station 114 may be a routing station, the fifth station 115 may be a routing station, the sixth station 116 may be a tantalum nitride deposition station, the seventh station 117 may be a copper deposition station, and the eighth station 118 may be a routing station that also serves as a buffer station. An object (e.g., substrate) may be transferred and processed within each process station 112-113 and 116-117. The magnitude of a vacuum within each station 111-118 may increase from station to station. For example, the magnitude of the vacuum in the seventh station 117 may exceed the magnitude of a vacuum in the other stations (e.g., stations 111-116 and 118).

The magnetic levitation assembly of the first station 111 and the magnetic levitation assembly of the eighth station 118 may cooperate to change the transfer direction of travel of the carrier. Additionally, the magnetic levitation assembly of the fourth station 114 and the magnetic levitation assembly of the fifth station 115 may cooperate to change the transfer direction of travel of the carrier. In other words, the carrier is able to be translated around the corners formed in the processing lines 102.

FIG. 1 has an X-Y-Z coordinate system to show the transfer direction of travel of the carrier and object through the substrate processing system 100. The arrows illustrate the direction that one or more carriers circulate within the processing line 102. During an example processing operation, the carrier receives an object entering the first station 111 in the X-direction from one or more front opening unified pods (FOUPS) 126 of a factory interface 124. The carrier is then conveyed to the second station 112 in the X-direction. The first station 111 also receives the carrier from the eighth station 118 in the Y-direction. After the carrier is conveyed into the second station 112, the carrier is conveyed to the fourth station 114 through the third station 113 in the X-direction. The carrier is then conveyed from the fourth station 114 to the fifth station 115 in the negative Y-direction. The carrier is then conveyed from the fifth station 115 to the eighth station 118 in the negative X-direction through the stations 116-117. The carrier is then conveyed in the Y-direction back into the first station 111. The now fabricated object (e.g. substrate 210 shown in FIG. 2A) is transferred to the FOUP 126. Another object 210 may then be placed onto the carrier in the first station 111 for another processing operation.

The second station 112 of the substrate processing system 100 is a degas station used to heat the object conveyed on the carrier to remove undesirable adhered, or adsorbed compounds, molecules or gases. Exemplary embodiments of degas stations that can be included in the substrate processing system 100 in the place of second station 112 are described in FIGS. 2A-6.

FIG. 2A is a cross-sectional view of a degas station 200. The degas station 200 includes, a housing 201 with a chamber 202 (e.g., vacuum chamber), a vacuum pump 205, a carrier 220, a magnetic levitation system 230 (e.g., magnetic levitation assembly), an upper heater assembly 240a, and a lower heater assembly 240b. The degas station 200 may be controlled by the controller 101. The directional axis used in FIG. 2A is the same directional axis used in FIG. 1.

The degas station 200 includes a degas assembly 290 used to degas a substrate 210 disposed on the carrier 220. The degas assembly 290 includes the upper heater assembly 240a and the lower heater assembly 240b. The degas assembly 290 may also include an actuator 261 used to move the upper heater assembly 240a and an actuator 261 used to move the lower heater assembly 240b. The degas assembly 290 may also include a first purge gas supply 281a to supply the purge gas to the upper heater assembly 240a through a gas supply line 282. The degas assembly 290 may also include a second gas supply 281b to supply the purge gas to the lower heater assembly 240b through another gas supply line 282.

The carrier 220 may be formed from one or more materials, with at least one portion of the carrier 220 including a ferromagnetic material such as stainless steel Grade 430 (SS430). In some embodiments, it is beneficial to select the material from which a second portion of the carrier 220 is made to include a material that can also withstand high processing temperatures, such as degas temperatures. For example, the carrier 200 may be made of a material that can maintain structural integrity at temperatures that exceed 100° C. In one example, the second portion or a third portion of the carrier 220 is made from a ceramic material (e.g., alumina, quartz, zirconia, etc.).

The carrier 220 includes an opening 221 configured to receive the substrate 210. Two support members 222 extend from the underside of the carrier 220. Opposing edges of the support members 222 are separated by a gap 223. The gap 223 is sized to allow lift pins, such as lift pins in stations 116, 117, to engage with the bottom side of the substrate 210. The opening 221 extends along the length of the carrier 220, and the substrate 210 can enter or exit either end of the opening 221. The two open ends allow for the carrier 220 to move in either direction along the X-direction of travel (e.g., moving into or out of the page) to transfer a substrate 210 to lift pins.

A plurality of magnets 225, such as permanent magnets, may be arranged adjacent the edges of the carrier 220 so that the magnets 225 may interact with at the first rails 231 of the magnetic levitation assembly 230. In some configurations, the plurality of magnets 225 may be arranged such that they form a Halbach array or other similar configuration. The plurality of magnets 225 may be disposed or embedded within the carrier 220.

The magnetic levitation assembly 230 is disposed within the housing 201. The magnetic levitation assembly 230 is configured to levitate and propel the carrier 220 to positions within the chamber 202 along a first conveyance plane, such as conveying the carrier 220 along the X-axis between a carrier degas position (e.g., position to facilitate degassing of the substrate 210) and a carrier transfer position (e.g., position to facilitate transferring the substrate 210 to a substrate support) within the housing 201. In some embodiments, the carrier 220 may be conveyed to a park position (e.g., position clear of a substrate support within the station to facilitate processing of the substrate 210 disposed on the substrate support). In some embodiments, the park position may be the same as the carrier degas position.

In some embodiments, the magnetic levitation assembly 230 may include a pair of spaced apart first rails 231 aligned to convey the carrier 220 along the first conveyance plane. In some embodiments, the magnetic levitation assembly 230 is disposed in the chamber 202. The first rails 231 include a plurality of magnets, such as electromagnets 232, configured to interact with the magnets 225 to levitate and/or convey the carrier 220 beneath the first rails 231. The plurality of magnetics may be a combination of permanent magnets and electromagnets. Electromagnets 232, such as coils, are shown disposed in the first rails 231 that can be used to generate an electromagnetic current to levitate and propel the carrier 220. The strength of the electromagnets 232 may be adjusted to maintain a consistent distance between the first rails 231 and the carrier 220 levitated beneath. The magnetic levitation assembly 230 may also include an optional pair of second rails 233 disposed beneath the pair of first rails 231. These second rails 233 are positioned parallel to the first rails 231, and the carrier 220 is conveyed between the first rails 231 and second rails 233 without contact. The second rails 233 may not include magnets. The non-magnetic second rails 233 are included to catch the carrier 220 in the event of a power failure to the electromagnets 232. In some embodiments, the non-magnetic second rails 233 may be used to discharge electrical build-up in the carrier 220 by lowering the carrier 220 into contact with the non-magnetic rails 233 using the first rails 231. In some embodiments, the second rails 233 include a plurality of magnets, such as electromagnets, to assist in levitating and propelling the carrier 220.

In some embodiments, the carrier 220 instead has features formed on the upper surface of the carrier 220 that interact with the electromagnets 232 to levitate and propel the carrier 220 instead of magnets 225 embedded within the carrier 220 as shown in FIG. 2A. These features may be a plurality of ferritic materials. For examples, the features may be an array of discrete features formed on the surface of the carrier 220. These features may be part of a magnetic levitation element coupled to the carrier 220.

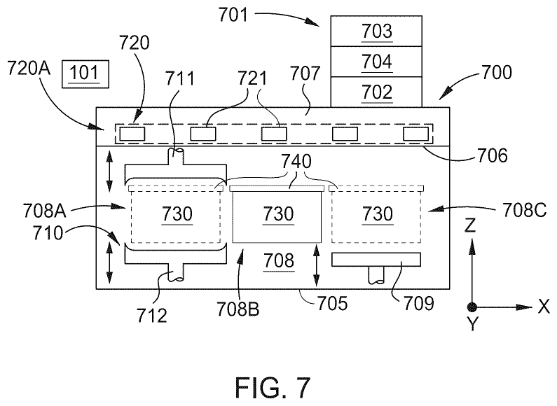

In some embodiments, each first rail 231 may include a plurality of linear stators arranged in a linear array, such as being a magnetic levitation actuator assembly 720A of station 700 shown in FIG. 7. Each first rail 231 comprising the linear array of stators may be configured to interact with an array of discrete features formed on the surface of the carrier 220. These features may be part of a magnetic levitation element coupled to the carrier 220. The plurality of stators and features together form a linear reluctance motor for providing both a contactless levitation and a contactless drive of the carrier 220. The linear reluctance motor of the apparatus according to embodiments described herein provides a linear motion of the carrier 220 along the first rails 231. In some embodiments, each first rail 231 is isolated from the chamber 202 by a membrane that at least partially defines the chamber 202.

The upper heater assembly 240a and the lower heater assembly 240b are at least partially disposed in the chamber 202. The upper heater assembly 240a and the lower heater assembly 240b each includes a heat source 241, a reflector 250, and a support 260. The heat source 241 is coupled to the reflector 250. The support 260 is coupled to the housing 201. The reflector 250 is supported in a position within the chamber 202 by the support 260. The purpose of the reflectors 250 are for both improved substrate degassing function and peripheral hardware protection from thermal energy from degas process.

The recess 252 has an inner diameter D₁ that may be larger than the diameter of the substrate 210 and/or the heat source 241. In some embodiments, the inner diameter D₁ of recess 252 of the upper reflector 250 is greater than a diameter D2 of the recess 252 of the lower reflector 250.

FIG. 2B is a perspective view of an exemplary heat source 241 that is a spiral wound heating element. FIG. 2C is a cross-sectional view of the exemplary heat source 241 that is a spiral wound heating element. The heat source 241 includes a wire filament 242 encased in an optically transparent casing 243, which can include tube or other similar structure formed of a ceramic or glass material. In some embodiments, the wire filament 242 is a tungsten wire and the casing 243 includes a quartz tube in which the filament 242 is disposed. The wire filament 242 and casing 243 are wound in a spiral shape with a central opening 244 in the middle. The radius R of the spiral wound heating element 241 may be greater than or equal to the radius of the substrate 210. For example, the radius R of the heating element 241 may be greater than a radius of a 150 mm substrate. The pitch of the wound heating element 241 may be selected based on desired thermal properties, such as increasing the pitch at certain locations to increase the heating effect over a desired surface of the substrate 210. For example, the pitch of the wound heating element 241 may decrease along radius R such that the amount of heat applied by the heating element 241 to the substrate decreases along radius R. Additionally, the pitch may be selected for uniform heating across a portion of the substrate to minimize areas of localized hotspots. Additionally, a thickness T of the casing 243, shown in FIG. 2C, may be varied along the length of the wound heating element 241. The thickness T may be varied to direct (e.g., focus) the heat at desired portions of the substrate 210. For example, the thickness T may be varied to uniformly distribute the heat emitted by the heating element 241 across the substrate 210. In some cases, the radiant power emitted by the heat source 241 adjusted along the length of the casing 243 by varying the power density of the wire filament 242 along the length of the casing 243, varying the thickness of the casing 243, and/or varying the type and/or coverage of a reflective and/or anti-reflective coating along the length of the casing 243.

The spiral wound heating element 241 also includes an input connection 245 and an output connection 246. Electrical power is supplied to the filament 242 at the input connection 245 which is converted to heat in the form of electromagnetic radiation. The residual electricity exits the spiral wound heating element 241 through the output connection 246 which is connected to a ground. A higher input voltage is required to deliver higher power. In some embodiments, the power supplied to the spiral wound heating element 241 is between 3 kW and 30 kW.

The first power supply 270a is connected to the heat source 241 of the upper heater assembly 240a by an electrical line 271. The second power supply 270b is connected to the heat source 241 of the lower heater assembly 240b by another electrical line 271. In some embodiments, the first and second power supplies 270a, 270b are the same power supply.

The heat source 241 discussed herein include one or more heating elements such as a spiral wound heating element as shown in FIG. 2B. The present disclosure contemplates that other heating sources with one or more heating elements may be used (in addition to or in place of the spiral wound heating element) for the various heat sources described herein. For example, discrete arc lamps, discrete halogen lamps, resistive heaters, light emitting diodes (LEDs), and/or lasers may be used for the various heat sources described herein. For example, the heat source 241 may be an array of discrete lamps, linear lamps, spiral heater, a combination, or in conjunction with non-lamp based heating elements. In some embodiments where the heat source is an array of discrete heat sources, the array may have a diameter that is greater than the diameter of the substrate 210.

The heat source 241 is used to increase the temperature of the substrate 210 to degas the substrate 210. In some embodiments, the heat source 241 can heat the substrate 210 to or above 100° C. to degas the substrate 210.

The reflector 250 is configured to reflect or absorb radiant heat from the heat source 241 to facilitate degassing the substrate 210. In some embodiments, the first reflector 250 has a reflective surface 251 configured to reflect the heat towards the substrate 210. The reflective surface 251 faces the heat source 241. The reflective surface 251 also faces the substrate 210 when the substrate 210 is positioned for degassing. The reflective surface 251 may have a three dimensional shape selected based on desired thermal uniformity. For example, the reflective surface 251 may be a concave surface as shown in FIG. 2A. In other embodiments, the reflector may be a flat surface. The reflector 250 discussed herein includes a reflective material such as stainless steel, aluminum, silver or other suitable material. For example, the reflective surface 251 may be fabricated from 316 stainless steel, Aluminum 6061-T6, stainless steel BA (cold rolled, bright annealed)/Nickle plated on Al 6061-T6 or a combination. In some embodiments, the reflective material includes any suitable material with thermal reflective properties. In some embodiments, a protective coating such as silicon oxide (SiO₂) can be used to ensure the reflectivity does not change over time.

The reflector 250 may have a recess 252 defined by the reflective surface 251. The heat source 241 may be disposed within or at least partially within the recess 252. In some embodiments, at least a portion of the heat source 241 is positioned beyond an end 253 of the reflector 250. For example, the reflector 250 may have a reflective surface 251 that is a flat surface with the first heat source 241 positioned thereon. In some embodiments, the substrate 210 is positioned away from surfaces of the upper and lower heating assemblies 240a, 240b, such as the reflective surface 251, to improve out-gassing rates from the substrate 210 on both sides of the substrate 210. The reflector 250 reduces the power needed to effectively degas the substrate 210. In some embodiments, the degas station 200 has a temperature ramp rate greater than 20° C./s.

The upper and lower heater assembly 240a, 240b may each include one or more gas ports 280 to supply a purge gas to both a top-side and a back-side of the substrate 210. The purge gas may be one or more an inert gases, such as argon (Ar). The purge gas is pumped through the one or more gas ports 280 towards the surface of the substrate 210 to direct away from the surface by purging, diluting, and preventing redeposition removed adsorbed gases, liquids and other surface contaminating materials, such as water vapor and particulates emitted from the substrate 210 during the degas process. In some embodiments, the one or more gas ports 280 is a gas port formed in the center of the reflective surface 251 as shown in FIG. 2A to uniformly distribute a gas across the surface of the substrate 210 during processing to improve the thermal heat transfer to the surface of the substrate 210.

In some embodiments, the gas port 280 is positioned above and aligned with the central opening 244 of the heat source 241 of the upper heater assembly 240a. In some embodiments the gas port 280 is positioned below and aligned with the central opening 244 of the heat source 241 of the lower heater assembly 240b. In some embodiments, the gas port 280 is positioned within the central opening 244.

The first purge gas supply 281a may supply the purge gas to the upper heater assembly 240a through the gas supply line 282 and the second gas supply 281b may supply the purge gas to the lower heater assembly 240b through another gas supply line 282. The gas supply lines 282 are coaxially disposed inside the supports 260. In some embodiments, the first and second gas supplies 281a, 281b are the same gas supply. In some embodiments, only one of the upper and lower heater assemblies 240a, 240b includes a gas port 280 and a purge gas supply.

The pump 205 is connected to the chamber 202 via a conduit 204 through the housing 201. The pump 205 evacuates the mixture of the purge gas, emitted gases, volatile materials, and/or particulates from the interior of the housing 201.

The pump 205 can also create and maintain a vacuum pressure within the degas station 200. For example, the pump 205 can reduce the pressure within the degas station 200 to a sub-atmospheric pressure between 10⁻⁶ Torr and 10 Torr. The pump 205 may be a turbopump, cryopump, roughing pump or other useful device that is able to maintain a desired pressure within the degas station 200.

In some embodiments, the support 260 is moveable relative to the housing 201 by an actuator 261 to move the respective heater assembly 240a, 240b in the Z-direction to position the heat source 241 at a desired distance from the substrate 210. In some embodiments, the heat sources 241 are disposed a distance from the substrate 210 ranging from 30 mm to 100 mm. The distance promotes heating uniformity of the substrate 210.

In some embodiments, the upper heater assembly 240a is moveable relative to the housing 201 while the lower heater assembly 240b has a support 260 that is fixedly attached to the housing 201. In other words, the lower heater assembly 240b does not have an actuator 261 configured to move the lower heater assembly 240b between positions in the Z-direction. In some embodiments, the lower heater assembly 240b is moveable relative to the housing 201 while the upper heater assembly 240a has a support 260 that is fixedly attached to the housing 201.

In some embodiments, the chamber 202 may include a region 203 configured to accommodate the movement of the upper heater assembly 240a in the Z-direction.

The substrate 210 is degassed within the degas station 200. In some embodiments, and as shown in FIG. 2A, the substrate 210 is degassed while disposed on the carrier 220 by emitting radiant heat from the heat sources 241. For example, the carrier 220 may be conveyed into the degas station 200 from the first station 111 and positioned in a carrier degas position between the opposing heating assemblies 240a, 240b. Degassing the substrate 210 on the carrier 220 eliminates the time needed to transfer the substrate 210 to lift pins which decreases the time needed to complete the process within the degas station 200. The upper and lower heater assemblies 240a, 240b may be moved in the Z-direction to position the heat source 241 thereof near the substrate 210 to decrease the volume of space between the opposing heater assemblies 240a, 240b. Decreasing volume between the opposing heater assemblies 240a, 240b reduces the electrical power necessary to degas the substrate 210. Additionally, positioning the heat sources 241 near the substrate 210 also minimizes the amount of heat that is transferred to other components of the degas station 200, such as the walls. The upper and lower heater assemblies 240a, 240b may also be moved to one or more positions to achieve a desired irradiance on the substrate and to achieve a desired ramp rate.

In some embodiments, the carrier 220 may be degassed while the substrate 210 is being degassed.

In some embodiments, a temperature sensor, such as a pyrometer may be included in the reflector 250, to measure the temperature of the substrate 210.

In some embodiments, the degas assembly 290 only includes one of the first purge gas supply 281a or the second purge gas supply 281b, with the a purge exhaust system (e.g., pumping system) replacing the omitted purge gas supply such that the purge gas exiting one port 280 flows in a uniform direction across the substrate 210 towards the other port 280 that the purge gas is being drawn into by the purge gas exhaust system. For example, the upper heater assembly 240a may be connected to the first purge gas supply 281a to facilitate injecting the purge gas at the top side of the substrate 210 while the port 280 of the lower heater assembly 240 is connected to a purge gas exhaust system that is drawing the purge gas injected into the station 200 through the port 280 in the upper heater assembly 240a into the port 280 of the lower heater assembly 240b.

In some embodiments, the purge gas supplies 281a,b may also include a purge gas exhaust system. In other words, the purge gas supply 281a,b may be used to selectively inject a purge gas through a port 280 or used to exhaust or exhaust the purge gas by drawing the purge gas into the port 280. For example, one purge gas supply may be used to inject gas while the other purge gas supply is used to exhaust purge gas to flow the purge gas across a surfaces of the substrate 210 for a period of time. In some embodiments, the purge gas supplies 281a,b may alternate between injecting and exhausting a purge gas to change which side of the substrate is having a gas flow across it. For example, the first purge gas supply 281a may be used to inject the purge gas for a period of time while the second purge gas supply 281b is used to evacuate the purge gas to facilitate the uniform flow of the purge gas across the top side of the substrate 210. The second purge gas supply 281b may then be used to inject the purge gas for a period of time while the first purge gas supply 281a is used to evacuate the purge gas to facilitate the uniform flow of the purge gas across the bottom side of the substrate 210.

In some embodiments, the flow rate of the purge gas injected by the first purge gas supply 281a and/or the second purge gas supply 281b during degassing is at least two times the volume between the opposing heater assemblies 240a, 240b per second. Injecting the purge gas at this rate improves the degas process.

In some embodiments, the port 280 may be a plurality of ports arranged to distribute purge gas. In some embodiments, the port(s) 280 is configured or the ports 280 are arranged to achieve a higher flow rate across the reflective surface 251 than the surface of the substrate 210 to keep the reflector 250 clean. In other words, the port(s) 280 can be used to decrease the buildup of material on the reflective surface 251 during the degassing process. In some embodiments, a blocker plate 285, as shown in FIG. 2A, is positioned within the reflector 250 such that gas exiting the gas port 280 is distributed along a desired flow path to facilitate avoiding buildup on the reflective surface 251. The blocker plate 285 may have one or more internal flow paths (e.g., apertures) that are configured to distribute the purge gas along the reflective surface 251 and the substrate 210.

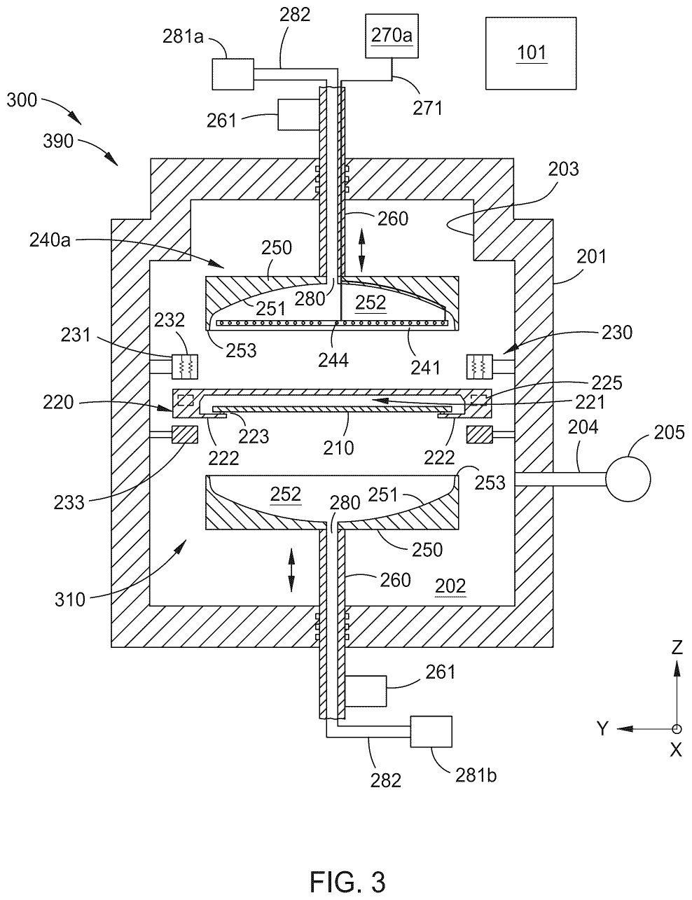

FIG. 3 is a cross-sectional view of an exemplary degas station 300. The degas station 300 has similar components as the degas station 200 as indicated by the reference signs without reciting the description of these components of the degas station 200 for brevity. The directional axis used in FIG. 3 is the same directional axis used in FIG. 1.

Degas station 300 has one heater assembly, shown as upper heater assembly 240a, which is disposed above a reflector assembly 310. The reflector assembly 310 includes a reflector 250 that is supported by a support 260. The difference between reflector assembly 310 and the lower heater assembly 240b is that the heat source 241 is omitted from this configuration of a degassing station.

The degas station 300 includes a degas assembly 390 used to degas the substrate 210 disposed on the carrier 220. In some embodiments, the carrier 220 may be degassed while the substrate 210 is being degassed. The degas assembly 390 includes the upper heater assembly 240a and the reflector assembly 310. The degas assembly 390 may also include an actuator 261 used to move the upper heater assembly 240a and an actuator 261 used to move the reflector assembly 310. The degas assembly 390 may also include the first purge gas supply 281a to supply the purge gas to the upper heater assembly 240a through the gas supply line 282. The degas assembly 390 may also include the second gas supply 281b to supply the purge gas to the reflector assembly 310 through another gas supply line 282.

In some embodiments, both the upper heater assembly 240a and the reflector assembly 310 are moveable relative to the housing 201 to one or more positions within the chamber 202. In some embodiments, only upper heater assembly 240a is moveable to one or more positions within the chamber 202 while the reflector assembly 310 is in a fixed position within the chamber 202 because the support 260 is fixedly attached to the housing 201. In some embodiments, only the reflector assembly 310 is moveable to one or more positions within the chamber 202 while the upper heater assembly 240a is in a fixed position within the chamber 202 because the support 260 is fixedly attached to the housing 201.

The substrate 210 is degassed within the degas station 300. In some embodiments, and as shown in FIG. 3, the substrate 210 is degassed while disposed on the carrier 220 by emitting heat from the heat source 241 of the upper heater assembly 240a. The upper heater assembly 240a and the reflector assembly 310 can be moved in the Z-direction decrease the volume of space between the opposing upper heater assembly 240a and the reflector assembly 310. Decreasing the volume reduces the electrical power necessary to degas the substrate 210. The position of the upper heater assembly 240a and the reflector assembly 310 may be moved to one or more positions to achieve a desired irradiance on the substrate 210 and to achieve a desired ramp rate.

In some embodiments, the degas assembly 390 only includes one of the first purge gas supply 281a or the second purge gas supply 281b, with the a purge exhaust system (e.g., pumping system) replacing the omitted purge gas supply such that the purge gas exiting one port 280 flows in a uniform direction across one side of the substrate 210 towards the other port 280 that the purge gas is being drawn into by the purge gas exhaust system. For example, the upper heater assembly 240a may be connected to the first purge gas supply 281a to facilitate injecting the purge gas at the top side of the substrate 210 while the port 280 of the reflector 310 is connected to a purge gas exhaust system that is drawing the purge gas injected into the station 300 through the port 280 in the upper heater assembly 240a into the port 280 of the reflector 310.

In some embodiments, the purge gas supplies 281a,b may also include a purge gas exhaust system. In other words, the purge gas supply 281a,b may be used to selectively inject a purge gas through a port 280 or used to exhaust or exhaust the purge gas by drawing the purge gas into the port 280. For example, one purge gas supply may be used to inject gas while the other purge gas supply is used to exhaust purge gas to flow the purge gas across a desired side of the substrate 210 for a period of time. In some embodiments, the purge gas supplies 281a,b may alternate between injecting and exhausting a purge gas to change which side of the substrate is having a gas flow across it. For example, the first purge gas supply 281a may be used to inject the purge gas for a period of time while the second purge gas supply 281b is used to evacuate the purge gas to facilitate the uniform flow of the purge gas across the top side of the substrate 210. The second purge gas supply 281b may then be used to inject the purge gas for a period of time while the first purge gas supply 281a is used to evacuate the purge gas to facilitate the uniform flow of the purge gas across the bottom side of the substrate 210.

In some embodiments, the flow rate of the purge gas injected by the first purge gas supply 281a and/or the second purge gas supply 281b during degassing is at least two times the volume between the opposing upper heater assembly 240a and the reflector assembly 310 per second. Injecting the purge gas at this rate improves the degas process.

In some embodiments, the upper heater assembly 240a and/or the reflector assembly 310 include a blocker plate 285 to facilitate distribution of the purge gas.

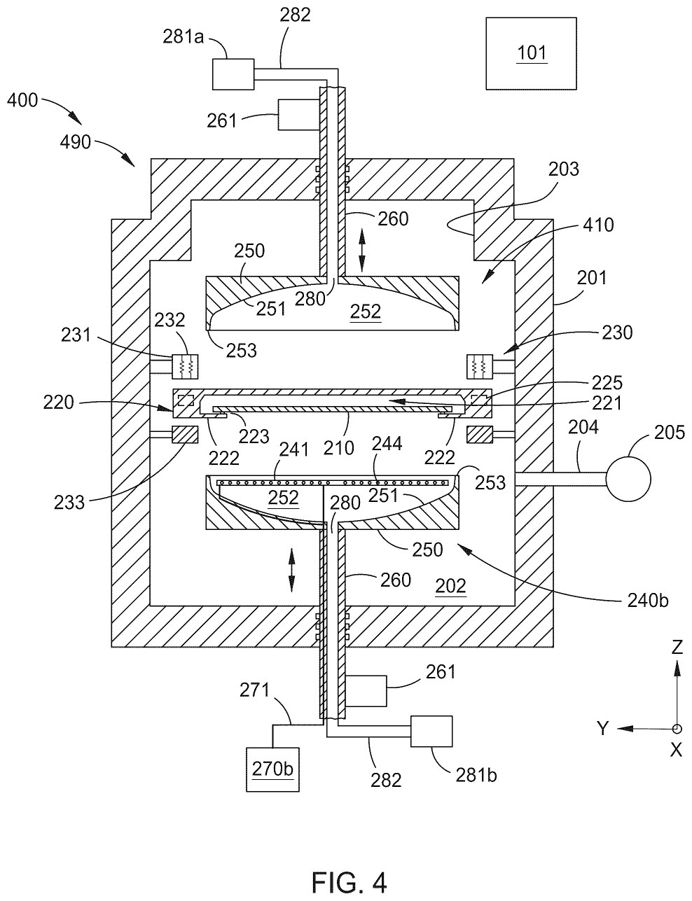

FIG. 4 is a cross-sectional view of an exemplary degas station 400. The degas station 400 has similar components as the degas station 200 as indicated by the reference signs without reciting the description of these components of the degas station 200 for brevity. The directional axis used in FIG. 4 is the same directional axis used in FIG. 1.

Degas station 400 has one heater assembly, shown as lower heater assembly 240b, which is disposed below a reflector assembly 410. The reflector assembly 410 is similar to the reflector assembly 310.

The degas station 400 includes a degas assembly 490 used to degas the substrate 210 disposed on the carrier 220. In some embodiments, the carrier 220 may be degassed while the substrate 210 is being degassed. The degas assembly 490 includes the reflector assembly 410 and the lower heater assembly 240b. The degas assembly 490 may also include the actuator 261 used to move the reflector assembly 410 and the actuator 261 used to move the lower heater assembly 240b. The degas assembly 490 may also include the first purge gas supply 281a to supply the purge gas to the reflector assembly 410 through the gas supply line 282. The degas assembly 490 may also include the second gas supply 281b to supply the purge gas to the lower heater assembly 240b through another gas supply line 282.

In some embodiments, both the lower heater assembly 240b and the reflector assembly 410 are moveable relative to the housing 201 to one or more positions within the chamber 202. In some embodiments, only lower heater assembly 240b is moveable to one or more positions within the chamber 202 while the reflector assembly 410 is in a fixed position within the chamber 202 because the support 260 is fixedly attached to the housing 201. In some embodiments, only the reflector assembly 410 is moveable to one or more positions within the chamber 202 while the lower heater assembly 240b is in a fixed position within the chamber 202 because the support 260 is fixedly attached to the housing 201.

The substrate 210 is degassed within the degas station 400. In some embodiments, and as shown in FIG. 4, the substrate 210 is degassed while disposed on the carrier 220 by emitting heat from the heat source 241 of the lower heater assembly 240a. The lower heater assembly 240b and the reflector assembly 410 can be moved in the Z-direction decrease the volume of space between the opposing lower heater assembly 240b and the reflector assembly 410. Decreasing the volume reduces the electrical power necessary to degas the substrate 210. The position of the lower heater assembly 240b and the reflector assembly 410 may be moved to one or more positions to achieve a desired irradiance on the substrate 210 and to achieve a desired ramp rate.

In some embodiments, the degas assembly 490 only includes one of the first purge gas supply 281a or the second purge gas supply 281b, with the a purge exhaust system (e.g., pumping system) replacing the omitted purge gas supply such that the purge gas exiting one port 280 flows in a uniform direction across one side of the substrate 210 towards the other port 280 that the purge gas is being drawn into by the purge gas exhaust system. For example, the reflector assembly 410 may be connected to the first purge gas supply 281a to facilitate injecting the purge gas at the top side of the substrate 210 while the port 280 of the lower heater assembly 240b is connected to a purge gas exhaust system that is drawing the purge gas injected into the station 400 through the port 280 in the reflector assembly 410 into the port 280 of the lower heater assembly 240b.

In some embodiments, the purge gas supplies 281a,b may also include a purge gas exhaust system. In other words, the purge gas supply 281a,b may be used to selectively inject a purge gas through a port 280 or used to exhaust or exhaust the purge gas by drawing the purge gas into the port 280. For example, one purge gas supply may be used to inject gas while the other purge gas supply is used to exhaust purge gas to flow the purge gas across a desired side of the substrate 210 for a period of time. In some embodiments, the purge gas supplies 281a,b may alternate between injecting and exhausting a purge gas to change which side of the substrate is having a gas flow across it. For example, the first purge gas supply 281a may be used to inject the purge gas for a period of time while the second purge gas supply 281b is used to evacuate the purge gas to facilitate the uniform flow of the purge gas across the top side of the substrate 210. The second purge gas supply 281b may then be used to inject the purge gas for a period of time while the first purge gas supply 281a is used to evacuate the purge gas to facilitate the uniform flow of the purge gas across the bottom side of the substrate 210.

In some embodiments, the flow rate of the purge gas injected by the first purge gas supply 281a and/or the second purge gas supply 281b during degassing is at least two times the volume between the opposing lower heater assembly 240b and the reflector assembly 410 per second. Injecting the purge gas at this rate improves the degas process.

In some embodiments, the lower heater assembly 240b and/or the reflector assembly 410 include a blocker plate 285 to facilitate distribution of the purge gas.

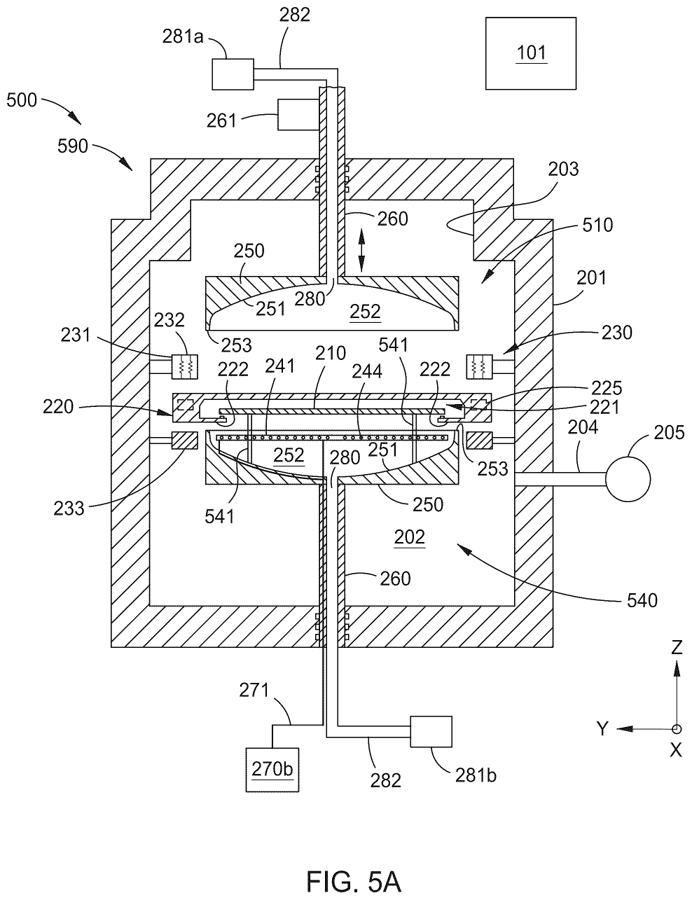

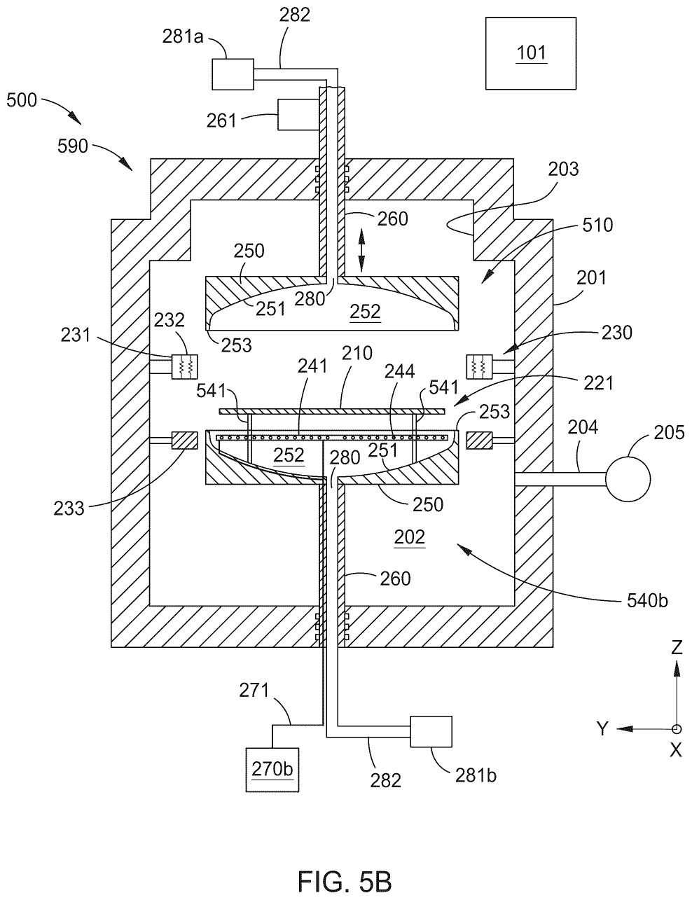

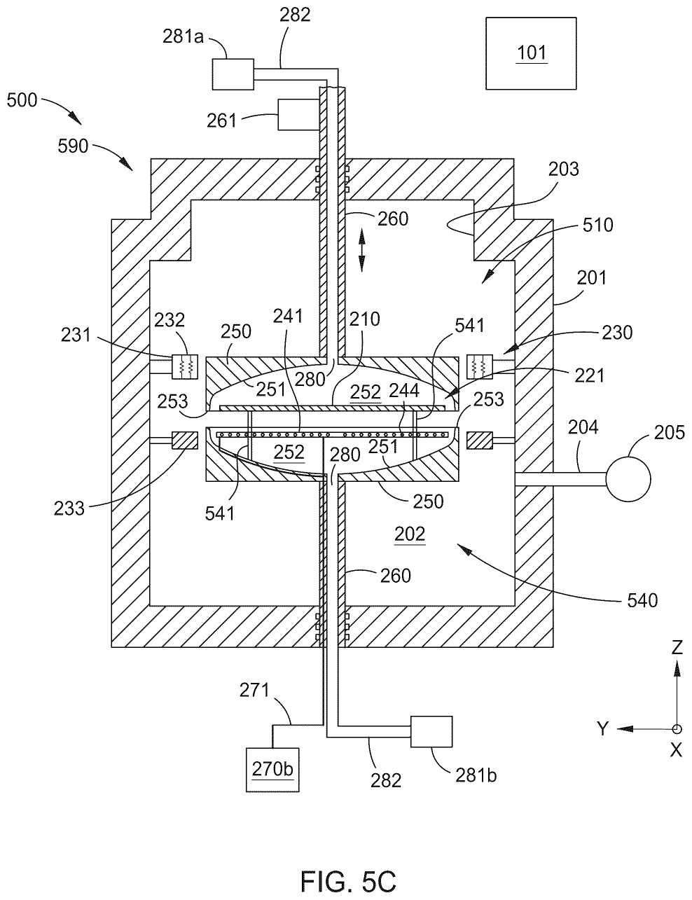

FIG. 5A-5C are cross-sectional views of an exemplary degassing station 500 where the substrate 210 is transferred to lift pins of a heater assembly from the carrier 220 prior to degassing. The degas station 500 has similar components as the degas station 200 as indicated by the reference signs without reciting the description of these components of the degas station 200 for brevity. The directional axis used in FIG. 5A-5C is the same directional axis used in FIG. 1.

Degas station 500 has one heater assembly, shown as lower heater assembly 540, which is disposed below a reflector assembly 510. The reflector assembly 510 is similar to the reflector assembly 410. The lower heater assembly 540 is similar to lower heater assembly 240b and includes a plurality of lift pins 541. The lift pins 541 may be attached to the reflector 250. In some embodiments, the lift pins 541 may be at least partially disposed in the recess 252. The lift pins 541 extend past the reflective surface 251 and through the heat source 241 such that the tips of the lift pins 541 protrude above the heat source 241. In some embodiments, the spiral wound heating element 241 may be wound such that a space is available for each lift pin to extend through without contacting the spiral wound heating element 241. In some embodiments, the lift pins extend from a plurality of sides of the heat sources 241. Additionally, the lower heater assembly 540 has a support 260 that is fixedly attached to the bottom of the housing 201. In other words, the lower hear assembly 540 is at a fixed position within the chamber 202. In some embodiments, the lift pins 541 are an integrated lift hoop with a shielding capability. The integrated lift hoop avoids direct exposure with the heat source 241 to the magnetic levitation assembly 230, the carrier 220 the slit valves 160 and the housing 201.

The degas station 500 includes a degas assembly 590 used to degas the substrate 210 disposed on the carrier 220. The degas assembly 590 includes the reflector assembly 510 and the lower heater assembly 540. The lower heater assembly 540 includes the lift pins 541 described above. The degas assembly 590 may also include the actuator 261 used to move the reflector assembly 510. The degas assembly 590 may also include the first purge gas supply 281a to supply the purge gas to the reflector assembly 510 through a gas supply line 282. The degas assembly 590 may also include the second gas supply 281b to supply the purge gas to the lower heater assembly 540 through another gas supply line 282.

The substrate 210 is conveyed into the degas station 500 on carrier 220. The magnetic levitation assembly 230 is used to position the carrier 220 in a carrier degas position above the lower heater assembly 540. The magnetic levitation assembly 230 is controlled, such as decreasing the current to the electromagnets 232 in the first rails 231, to lower the carrier 220 relative to the first rails 231. As the carrier 220 lowers, the lift pins 541 engage the bottom side of the substrate 210. Continued lowering of the carrier 220 causes the substrate 210 to disengage with the support members 222 of the carrier 220 as shown in FIG. 5A. The carrier 220 is then moved clear of the degas assembly 590, such as being moved to a park position within the station 500, once the substrate 210 is transferred to the lift pins 541 to move the carrier clear of the substrate 210 so that the reflector assembly 510 may be lowered without contacting the carrier 220.

FIG. 5B illustrates the substrate 210 transferred to the lift pins 541 after the carrier 220 moved to a position clear of the substrate 210. The reflector assembly 510 is then lowered relative to the lower heater assembly 540 to a degas position. The substrate 210 may be disposed within the recess 252 of the reflector assembly 510 with a clearance between reflective surface 251 and the substrate 210 when in the degas position as shown in FIG. 5C. Lowering the reflector assembly 510 to dispose the substrate 210 within the recess 252 reduces the volume between the opposing lower heater assembly 540 and reflector assembly 510, which reduces the amount of electrical power needed to degas the substrate. The substrate 210 is then degassed by heat transmitted by the heat source 241. Purge gas may be injected into the volume from a gas port 280 disposed in at least one of the reflector assembly 510 and the lower heater assembly 540.

In some embodiments, the degas assembly 590 only includes one of the first purge gas supply 281a or the second purge gas supply 281b, with the a purge exhaust system (e.g., pumping system) replacing the omitted purge gas supply such that the purge gas exiting one port 280 flows in a uniform direction across one side of the substrate 210 towards the other port 280 that the purge gas is being drawn into by the purge gas exhaust system. For example, the reflector assembly 510 may be connected to the first purge gas supply 281a to facilitate injecting the purge gas at the top side of the substrate 210 while the port 280 of the lower heater assembly 540 is connected to a purge gas exhaust system that is drawing the purge gas injected into the station 500 through the port 280 in the reflector assembly 510 into the port 280 of the lower heater assembly 540.

In some embodiments, the purge gas supplies 281a,b may also include a purge gas exhaust system. In other words, the purge gas supply 281a,b may be used to selectively inject a purge gas through a port 280 or used to exhaust or exhaust the purge gas by drawing the purge gas into the port 280. For example, one purge gas supply may be used to inject gas while the other purge gas supply is used to exhaust purge gas to flow the purge gas across a desired side of the substrate 210 for a period of time. In some embodiments, the purge gas supplies 281a,b may alternate between injecting and exhausting a purge gas to change which side of the substrate is having a gas flow across it. For example, the first purge gas supply 281a may be used to inject the purge gas for a period of time while the second purge gas supply 281b is used to evacuate the purge gas to facilitate the uniform flow of the purge gas across the top side of the substrate 210. The second purge gas supply 281b may then be used to inject the purge gas for a period of time while the first purge gas supply 281a is used to evacuate the purge gas to facilitate the uniform flow of the purge gas across the bottom side of the substrate 210.

In some embodiments, the flow rate of the purge gas injected by the first purge gas supply 281a and/or the second purge gas supply 281b during degassing is at least two times the volume between the opposing lower heater assembly 540 and reflector assembly 510 per second. Injecting the purge gas at this rate improves the degas process.

In some embodiments, the lower heater assembly 540 and/or the reflector assembly 510 include a blocker plate 285 to facilitate distribution of the purge gas.

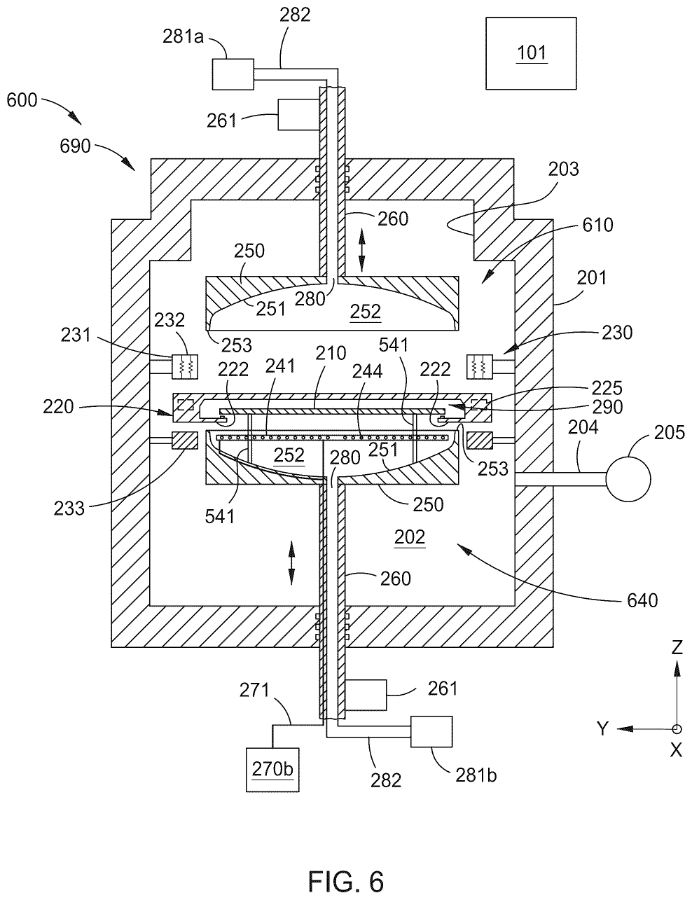

FIG. 6 is a cross-sectional view of an exemplary degas station 600 where the substrate 210 is transferred to a lift pins of a heater assembly from the carrier 220 prior to degassing. The degas station 600 has similar components as the degas stations 200, 500 as indicated by the reference signs without reciting the description of these components of the degas stations 200, 500 for brevity. The directional axis used in FIG. 6 is the same directional axis used in FIG. 1.

Degas station 600 has one heater assembly, shown as lower heater assembly 640, which is disposed below a reflector assembly 610. The reflector assembly 610 is similar to the reflector assembly 510. The lower heater assembly 640 is similar to lower heater assembly 540 except that the lower heater assembly 540 has a support that is not fixedly attached to the housing 201 and therefore is moveable to one or more positions within the chamber 202 by an actuator 261.

The degas station 600 includes a degas assembly 690 used to degas the substrate 210 disposed on the carrier 220. The degas assembly 690 includes the reflector assembly 610 and the lower heater assembly 640. The lower heater assembly 640 includes the lift pins 541. The degas assembly 690 may also include the actuator 261 used to move the reflector assembly 610 and another actuator 261 used to move the lower heater assembly 640. The degas assembly 690 may also include the first purge gas supply 281a to supply the purge gas to the reflector assembly 610 through a gas supply line 282. The degas assembly 690 may also include the second gas supply 281b to supply the purge gas to the lower heater assembly 640 through another gas supply line 282.

The substrate 210 is conveyed into the degas station 600 on carrier 220. The magnetic levitation assembly 230 is used to position the carrier 220 in a carrier degas position above the lower heater assembly 640 as shown in FIG. 6. The actuator 261 of the lower heater assembly 640 causes the lift pins 541 to engage the underside of the substrate 210 and disengage the substrate 210 from the support members 222. The carrier 220 is then moved from the carrier degas position, such as to a park position within the station 600, once the substrate 210 is transferred to the lift pins 541 to move the carrier clear of the substrate 210 so that the reflector assembly 610 may be lowered without contacting the carrier 220.

The reflector assembly 610 is then lowered relative to the lower heater assembly 640 to a degas position, such as the position of reflector assembly 510 shown in FIG. 5C. The substrate 210 may then be degassed by the heat source 241, and a purge gas may be flowed over the surface of the substrate 210 during degassing.

In some embodiments, the degas assembly 690 only includes one of the first purge gas supply 281a or the second purge gas supply 281b, with the a purge exhaust system (e.g., pumping system) replacing the omitted purge gas supply such that the purge gas exiting one port 280 flows in a uniform direction across one side of the substrate 210 towards the other port 280 that the purge gas is being drawn into by the purge gas exhaust system. For example, the reflector assembly 610 may be connected to the first purge gas supply 281a to facilitate injecting the purge gas at the top side of the substrate 210 while the port 280 of the lower heater assembly 640 is connected to a purge gas exhaust system that is drawing the purge gas injected into the station 600 through the port 280 in the reflector assembly 610 into the port 280 of the lower heater assembly 640.

In some embodiments, the purge gas supplies 281a,b may also include a purge gas exhaust system. In other words, the purge gas supply 281a,b may be used to selectively inject a purge gas through a port 280 or used to exhaust or exhaust the purge gas by drawing the purge gas into the port 280. For example, one purge gas supply may be used to inject gas while the other purge gas supply is used to exhaust purge gas to flow the purge gas across a desired side of the substrate 210 for a period of time. In some embodiments, the purge gas supplies 281a,b may alternate between injecting and exhausting a purge gas to change which side of the substrate is having a gas flow across it. For example, the first purge gas supply 281a may be used to inject the purge gas for a period of time while the second purge gas supply 281b is used to evacuate the purge gas to facilitate the uniform flow of the purge gas across the top side of the substrate 210. The second purge gas supply 281b may then be used to inject the purge gas for a period of time while the first purge gas supply 281a is used to evacuate the purge gas to facilitate the uniform flow of the purge gas across the bottom side of the substrate 210.

In some embodiments, the flow rate of the purge gas injected by the first purge gas supply 281a and/or the second purge gas supply 281b during degassing is at least two times the volume between the opposing lower heater assembly 640 and reflector assembly 610 per second. Injecting the purge gas at this rate improves the degas process.

In some embodiments, the lower heater assembly 640 and/or the reflector assembly 610 include a blocker plate 285 to facilitate distribution of the purge gas.

FIG. 7 illustrates schematic side view of an exemplary process station process station 705. Process station 705 may be substituted for a process station (e.g., stations 112-113 and 116-117) of the processing system 100 of FIG. 1. The process station 705 is configured for contactless transportation of the carrier 730. The process station 705 includes a process chamber 701, a magnetically permeable membrane 706, a substrate support 709, a degas assembly 710, and a magnetic levitation assembly 720. A substrate 210 conveyed by a carrier can be degassed by the degas assembly 710 prior to being processed in the process chamber 701.

The magnetically permeable membrane 706 is disposed between the carrier 730 and the magnetic levitation assembly 720. The pressure may be different on opposing sides of the membrane 706. For example, the membrane 706 may be a barrier that isolates a first region 707 (e.g., cavity) of the process station 705 that includes the magnetic levitation assembly 720 from a second region 708 (e.g., vacuum chamber) where the carrier 730 is located. The first region 707 may be at atmospheric pressure while the second region 708 may be at a vacuum pressure.

The carrier 730 includes one or more a magnetic levitation elements 740 that allow the carrier 730 to be levitated and transported through the process station 705. Each magnetic levitation element 740 may be a track that is aligned in the X-direction or the Y-direction. The magnetic levitation element 740 may be a substantially straight magnetic levitation element 740, or may at least include one or more straight portions that allow the carrier 730 to be contactlessly transported through the substrate processing system 100 by use of the components within the magnetic levitation assembly 720. The magnetic levitation element 740 may define a transportation direction (or transport direction), along which the carrier 730 is contactlessly transported. In one example, as illustrated in FIG. 7, the carrier 730, which includes one or more magnetic levitation elements 740, is transferred through the process station 705, and to and from other adjacent process stations 705 (not shown), by magnetic levitation, without the carrier 730 contacting the walls or components within the process station 705.

The process station 705 includes a magnetic levitation assembly 720 that includes a plurality of magnetic levitation actuator assemblies 720A. The plurality of magnetic levitation actuator assemblies 720A interact with the one or more magnetic levitation elements 740 of the carrier to contactlessly transport the carrier 730 to one or more positions in the second region 708 disposed below the process chamber 701. The magnetic levitation actuator assemblies 720A each include a plurality of linear stators 721 configured to levitate and convey the carrier 730 by the generation of a magnetic field that extends through the membrane 706 to interact with the carrier 730 and the time varying control of the generated magnetic field. In some embodiments, a magnetic levitation actuator assembly 720A may include two or more, three or more, five or more, or ten or more linear stators 721, depending on the desired length of the magnetic levitation elements 740, which is often referred to herein as a magnetic levitation element 740. Alternatively, the magnetic levitation actuator assemblies 720A may include one elongated linear stator 721 extending along the entire length of a magnetic levitation element 740. The number of linear stators 721 shown in FIG. 7 is an example, and a greater or lesser number of linear stators 721 may be used.

The linear stator(s) 730 may be arranged in a magnetic levitation linear array to guide a corresponding magnetic levitation element 740 of the carrier 730 underneath. For example, a plurality of linear stators 721 may be disposed one after the other in a linear array (e.g., row) extending in the X and/or Y-direction, such as the linear stators 721 shown in FIG. 7. In some embodiments, the one or more linear stators 721 may be configured to remain stationary during contactless transportation of the carrier 730 along the magnetic levitation element 740 since the one or more linear stators 721 are coupled to a wall (e.g., top wall or side wall) of the housing of the process station 705 or at least partially supported by contact with the membrane 706.

The one or more linear stators 721 including the electromagnets may, together with the magnetic levitation element 740, form a linear reluctance motor for providing both a contactless levitation and a contactless drive of the carrier 730. A linear reluctance motor is configured for providing a linear motion, or translational motion, of the carrier 730. A linear motor is distinguished from a rotary motor, which provides a rotational motion. The linear reluctance motor of the apparatus according to embodiments described herein provides a linear motion of the carrier 730 along the magnetic levitation assembly 720.

The carrier 730 may be configured to transport one or more substrates 140 due to the interaction of the magnetic fields generated by the linear stators 721 of the magnetic levitation assembly 720 and commands sent by a controller 101 of the substrate processing system 100. The carrier 730 may be transported in the X-direction or negative X-direction, as illustrated in FIG. 7. The carrier 730 may also be transported in the Y-direction or negative Y-direction.

In some embodiments, the process station 705 includes a plurality of membranes 706. In some embodiments, the process station 705 may have multiple first regions 707, and each first region 707 is separated from the second region 708 (e.g., transport region) by the respective membrane 706. Each first region 707 may be partially defined by one or more walls of the housing. For example, a first plurality of magnetic levitation actuator assemblies 720A may be disposed in one first region 707 of the process station 705 that is parallel to a second plurality of magnetic levitation actuator assemblies 720A disposed in a different first region 707 of the process station 705. The first plurality of magnetic levitation actuator assemblies 720A may interact with a first magnetic levitation element 740 of the carrier 730 that is parallel to a second magnetic levitation element 740 of the carrier 730.

The process chamber 701 includes a process kit assembly 702, and a source assembly 703. In some embodiments, the process chamber 701 is maintained at a vacuum pressure, such that a processing region 704 of the process chamber 701 is at a pressure that is less than 760 Torr, or even at a pressure between 1×10-7 and 760 Torr, such as between 1 milliTorr (mTorr) and 500 Torr. As shown, the substrate support 709 is disposed below the process kit assembly 702 and source assembly 703. The carrier 730 is shown in a carrier degas position 708A, as indicated by reference sign 708A, and is moveable to a park position (shown in dashed lines and indicated by the reference sign 708B) within the second region 708. The carrier 730 is also moveable to a carrier transfer position (shown in dashed lines and indicated by reference sign 708C) above the substrate support 709.

The substrate support 709 is moveable in the Z-direction within the second region 708 to one or more positions. While the carrier 730 is moving within the process station 705, the substrate support 709 may be positioned in a lower position to allow the carrier 730 to move to through and/or to one or more positions within the second region 708 without contacting the substrate support 709.

The carrier 730 is moved to the carrier transfer position 708C above the substrate support 709 to facilitate the transfer of the substrate 210 on the carrier 730 to lift pins of the substrate support 709 disposed at a lower position (e.g. position shown in FIG. 7). The carrier 730 is then moved to the park position 708B (e.g., position between degas assembly 710 and the process chamber 710) after the substrate 210 is transferred to the lift pins. The carrier 730 is clear from the substrate support 709 when in the park position 708B to allow the substrate support 709 to move vertically from the lower position to a process position with the transferred substrate 210 disposed thereon.

The substrate support 709 is engaged with the process kit assembly 702 when in the process position. In some embodiments, the process kit assembly 702 includes one or more components to seal against the substrate support 709 when the substrate support 709 is in the process position. For example, the substrate support 709 and process kit assembly 702 may at least partially defined the process region 604 within the process station 705 where the substrate 210 is subjected to a process performed by the source assembly 703. The process region 704, which is defined by surfaces of the substrate 210, the substrate support 709, the process kit assembly 702 and the source assembly 703, is isolated from the second region 708 when the substrate support 709 is in the process position. For example, the source assembly 703 may be configured to deposit a layer via a physical vapor deposition (PVD) process onto the substrate 210. Once the process performed by the source assembly 703 is complete, the substrate support 709 is lowered from the process position to the lower position to allow the carrier 730 to return to the carrier transfer position 708C where the substrate 210 is transferred from the lift pins back onto the carrier 730.

The source assembly 703 may be adapted to perform a physical vapor deposition (“PVD”), chemical vapor deposition (“CVD”), plasma enhanced chemical vapor deposition (“PECVD”), atomic layer deposition (“ALD”), plasma enhanced atomic layer deposition (“PEALD”), etch, lithography, ion implantation, ashing, cleaning, thermal process (e.g., rapid thermal processing, anneal, cool down, thermal management control) degas, and/or other useful substrate processes.

The degas assembly 710 is configured to degas a substrate 210 (shown in FIG. 2A). In some embodiments, the degas assembly 710 can be used to degas the carrier 730 while the substrate 210 is being degassed thereon. In some embodiments, the degas assembly 730 can also be used to degas the carrier 730 without a substrate 210 disposed thereon. The degas assembly 710 includes a first assembly 711 and a second assembly 712 at least partially disposed in the second region 708. The first and second assemblies 711, 712 may be isolated from the first region 707 by the one or more membranes 706. The degas assembly may be any of degas assemblies above, such as the degas assembly 290 of FIG. 2A, the degas assembly 390 of FIG. 3, the degas assembly 490 of FIG. 4, the degas assembly 590 of FIGS. 5A-5C, and the degas assembly 690 of FIG. 6. For example, the first assembly 711 may be the upper assembly 240a and the second assembly 712 may be the lower assembly 240b shown in FIGS. 2A, 3, and 4. For example, the first assembly 711 may be the reflector assembly 510 and the second assembly 712 may be the lower heater assembly 540 shown in FIG. 5. For example, the first assembly 711 may be the reflector assembly 610 and the second assembly 712 may be the lower heater assembly 640 shown in FIG. 6.

The process station 705 further includes the pump 205 as shown in FIGS. 2A, and 3-6. In some embodiments, the pump 205 is used to remove purge gas used in the degassing process from the second region 708. The pump 205 also may be used to bring and maintain the second region 708 at the vacuum pressure. Purge gas may also be evacuated from the process station 705 through one of the ports 280 of the first assembly 711 or second assembly 712 that is connected to a purge gas exhaust system.

The carrier 730 is disposed between the first assembly 711 and the second assembly 712 in the carrier degas position 708A. In some embodiments, the degas assembly 710 is configured to degas a substrate 210 that is disposed on a carrier 730 located at the carrier degas position 708A. In some embodiments, the substrate 210 is moved to the carrier degas position 708A where the substrate 210 is then transferred to the degas assembly 710 from the carrier 730, such as being transferred to lift pins (e.g., lift pins 541) of the degas assembly 710. The carrier 730 is moved to the park position 708B during the degassing. After the substrate 210 is degassed, then the carrier 730 is returned to the carrier degas position 708A to receive the substrate 210. The carrier 730 is moved to the transfer position 708C after the substrate 210 is returned to the carrier 730 to facilitate the transfer the substrate 210 onto the substrate support 709 for processing in the process chamber 701.

In some embodiments, the carrier degas position is the same as the park position. For example, the carrier 730 may be moved between the first assembly 711 and second assembly 712 to facilitate degassing of the substrate 210. The carrier 730 may then also be parked between the first assembly 711 and the second assembly 712 while the substrate 210 is processed within the process chamber 701. This allows for a station 700 with a shorter length since the separate park position 708B is omitted.

In some embodiments, a first substrate 210 conveyed by a first carrier 730 may be degassed by the degas assembly 710 while a second substrate 210 conveyed by a second carrier 730 is processed within the process chamber 701. For example, the process station 705 may be sized such that both carriers may be parked in a separate park position. In some embodiments, the process station 705 has one park position for both carriers 730. For example, the first carrier 730 may be parked in the park position 708B while the substrate 130 previously disposed thereon is processed in the process chamber 710 while the second carrier 730 is disposed in the carrier degas position to allow the degas assembly to degas the substrate 210 disposed thereon.

In one embodiment, a degas station, includes a housing; a magnetic levitation system coupled to the housing configured to levitate and move a carrier within the housing; a first heater assembly disposed in the housing, the first heater assembly including: a first support; a first reflector disposed within the housing by the first support; and a first heat source coupled to reflector; a second heater assembly disposed in the housing above the first heater assembly, the second heater assembly including: a second support; a second reflector disposed within the housing by the second support; and a second heat source coupled to the second reflector; and at least one substrate support member disposed between the first heater assembly and the second heater assembly.

In one or more embodiments of the degas station, the first heater assembly further comprises: a first gas line disposed inside the first support and coaxially extending to a first gas port formed in a first reflective surface of the first reflector.

In one or more embodiments of the degas station, the first heat source comprises a spiral heating element wound around a central opening and attached the first reflected surface of the first reflector, wherein the first gas port is aligned with the central opening.

In one or more embodiments of the degas station, the first heater assembly further comprises: a first actuator coupled to the first support, wherein the first actuator is configured to move the first heat source to one or more positions within the housing.

In one or more embodiments of the degas station, the second heater assembly further comprises: a second gas line coaxially disposed inside the second support and extending to a second gas port formed in a second reflective surface of the second reflector.

In one or more embodiments of the degas station, the second heater assembly further comprises: a second actuator coupled to the second support, wherein the second actuator is configured to move the second heat source to one or more positions within the housing.

In one or more embodiments of the degas station, the first support is fixed to the housing to maintain the first heat source and the first reflector in a fixed position.

In one embodiment, a degas station includes a housing; a magnetic levitation system coupled to the housing and configured to levitate and move a carrier within the housing; a first heater assembly disposed in housing, comprising: a first support connected to the housing; a first reflector connected to the first support; and a first heat source coupled to the first reflector; a reflector assembly disposed in the housing, comprising: a second support connected to the housing; and a second reflector supported by the second support; and at least one substrate support member disposed between the first heater assembly and the reflector assembly.

In one or more embodiments of the degas station, the first heater assembly further comprises: a first gas line disposed inside the first support and extending to a first gas port formed in a first reflective surface of the first reflector.

In one or more embodiments of the degas station, the first heater assembly further comprises: a first actuator coupled to the first support, wherein the first actuator is configured to move the first heat source to one or more positions within the housing.

In one or more embodiments of the degas station, the reflector assembly further comprises: a second gas line disposed inside the second support and extending to a second gas port formed in a second reflective surface of the second reflector.

In one or more embodiments of the degas station, the second reflective surface is a concave or a flat surface.

In one or more embodiments of the degas station, the reflector assembly further comprises: an actuator coupled to the second support, wherein the actuator is configured to move the reflector assembly to one or more positions within the housing.

In one embodiment, a degas station includes a housing; a magnetic levitation system coupled to the housing and configured to levitate and move a carrier within the housing; a reflector assembly disposed in the housing, including: a first support coupled to the housing; a first reflector connected to the first support; a heater assembly disposed in the housing beneath the reflector assembly, including: a second support coupled to the housing; a second reflector connected to the second support; a heat source connected to the second reflector; and at least one lift pin; and at least one substrate support member disposed between the heater assembly and the reflector assembly.

In one or more embodiments of the degas station, the at least one lift pin extend from the second reflector and through the heat source such that a portion of the at least one lift pin protrudes from the heat source or a plurality of sides of the heat source.

In one or more embodiments of the degas station, the heater assembly includes an actuator coupled to the second support and configured to move the second reflector, heating unit, and at least one lift pin between one or more positions within the housing.

In one or more embodiments of the degas station, the reflector assembly further comprises: a first gas line disposed inside the first support and extending to a first gas port formed in a first reflective surface of the first reflector.

In one or more embodiments of the degas station, the heating assembly further comprises: a second gas line disposed inside the second support and extending to a second gas port formed in a second reflective surface of the second reflector.

In one embodiment, a method of degassing a substrate in a degas station includes positioning a substrate disposed on a carrier above one or more lift pins of a first heater assembly and below a reflector assembly; transferring the substrate from the carrier to the lift pins by lowering the carrier; moving the carrier from under the reflector assembly; lowering the reflector assembly to place a reflector of the reflector assembly in a degas position above the substrate; and degassing the substrate with the first heating unit.

In one or more embodiments of the method of degassing the substrate, the substrate is disposed in a recess of the reflector when the reflector assembly is in the degas position.

In one or more embodiments of the method of degassing the substrate degassing the substrate further includes: pumping purge gas through a gas port formed in the reflector assembly.

In one embodiment, a method of degassing a substrate in a degas station includes positioning a substrate disposed on a carrier above one or more lift pins of a reflector assembly and above a heater assembly in a first position; transferring the substrate from the carrier to the lift pins by raising the heater assembly from the first position to a second position to engage the lift pins with the substrate; moving the carrier from under the reflector assembly; lowering the reflector assembly to place a reflector of the reflector assembly in a degas position above the substrate; and degassing the substrate with the heater assembly.

In one or more embodiments of the method, the substrate is disposed in a recess of the reflector when the reflector assembly is in the degas position.

In one or more embodiments of the method, degassing the substrate further includes: pumping purge gas through a gas port formed in the reflector assembly.

While the foregoing is directed to embodiments of the present disclosure, other and further embodiments of the disclosure may be devised without departing from the basic scope thereof, and the scope thereof is determined by the claims that follow.

What is claimed is:

1. A station, comprising:
a housing defining a vacuum chamber;
a magnetic levitation system coupled to the housing and configured to levitate and move a carrier within the housing;
a first heater assembly at least partially disposed in the vacuum chamber, comprising:
a first support connected to the housing;
a first reflector connected to the first support and comprising a reflective surface; and
a first heat source disposed over the reflective surface of the first reflector;
a reflector assembly at least partially disposed in the vacuum chamber, comprising:
a second support connected to the housing; and
a second reflector supported by the second support; and
at least one substrate support member disposed between the first heater assembly and the reflector assembly.

2. The station of claim 1, wherein the at least one substrate support member comprises at least one lift pin.

3. The station of claim 1, wherein the at least one substrate support member comprises a support member of the carrier.

4. The station of claim 1, further comprising:
a processing chamber disposed in the housing; and
a substrate support disposed below the processing chamber and adjacent to the first heater assembly.

5. The station of claim 4, wherein no slit valve is between the processing chamber and the first heater assembly.

6. The station of claim 1, wherein the first heater assembly further comprises:
a first gas line disposed inside the first support and extending to a first gas port formed in a first reflective surface of the first reflector.

7. The station of claim 1, wherein the first heater assembly further comprises:
a first actuator coupled to the first support, wherein the first actuator is configured to move the first heat source to one or more positions within the housing.

8. The station of claim 1, wherein the reflector assembly further comprises:
a second gas line disposed inside the second support and extending to a second gas port formed in a second reflective surface of the second reflector.

9. A station, comprising:
a housing;
a magnetic levitation system coupled to the housing configured to levitate and move a carrier within the housing;
a first heater assembly disposed in the housing, the first heater assembly including:
a first support;
a first reflector disposed within the housing by the first support and having a reflective surface; and
a first heat source disposed over the reflective surface of reflector;
a second heater assembly disposed in the housing above the first heater assembly, the second heater assembly including:
a second support;
a second reflector disposed within the housing by the second support; and
a second heat source coupled to the second reflector; and
at least one substrate support member disposed between the first heater assembly and the second heater assembly.

10. The station of claim 9, wherein the first heater assembly further comprises:
a first gas line disposed inside the first support and coaxially extending to a first gas port formed in a first reflective surface of the first reflector.

11. The station of claim 10, wherein the first heat source comprises a spiral heating element wound around a central opening and attached the first reflective surface of the first reflector, wherein the first gas port is aligned with the central opening.

12. The station of claim 9, wherein the first heater assembly further comprises:
a first actuator coupled to the first support, wherein the first actuator is configured to move the first heat source to one or more positions within the housing.

13. The station of claim 9, wherein the second heater assembly further comprises:
a second gas line coaxially disposed inside the second support and extending to a second gas port formed in a second reflective surface of the second reflector.

14. The station of claim 9, wherein the second heater assembly further comprises:
a second actuator coupled to the second support, wherein the second actuator is configured to move the second heat source to one or more positions within the housing.

15. The station of claim 9, wherein the first support is fixed to the housing to maintain the first heat source and the first reflector in a fixed position.

16. A station, comprising:
a housing;
a magnetic levitation system coupled to the housing and configured to levitate and move a carrier within the housing;
a reflector assembly disposed in the housing, including:
a first support coupled to the housing; and
a first reflector connected to the first support;
a heater assembly disposed in the housing beneath the reflector assembly, including:
a second support coupled to the housing;
a second reflector connected to the second support;
a heat source connected to the second reflector; and
at least one lift pin.

17. The station of claim 16, wherein the at least one lift pin extends from the second reflector and through the heat source such that a portion of the at least one lift pin protrudes from the heat source or a plurality of sides of the heat source.

18. The station of claim 17, wherein the heater assembly includes an actuator coupled to the second support and configured to move the second reflector, heating unit, and at least one lift pin between one or more positions within the housing.

19. The station of claim 16, wherein the reflector assembly further comprises:
a first gas line disposed inside the first support and extending to a first gas port formed in a first reflective surface of the first reflector.

20. The station of claim 16, wherein the heating assembly further comprises:
a second gas line disposed inside the second support and extending to a second gas port formed in a second reflective surface of the second reflector.
